(19) United States
(12) Patent Application Publication
(10) Pub. No.: US 2025/0286520 A1
(43) Pub. Date: Sep. 11, 2025

(54) RLC NETWORK FOR LNA STABILITY

(71) Applicant: pSemi Corporation, San Diego, CA (US)

(72) Inventors: Ymmen GOEL, San Diego, CA (US); Nebojsa STANIC, San Diego, CA (US); Jing LI, San Diego, CA (US)

(21) Appl. No.: 18/601,366

(22) Filed: Mar. 11, 2024

(51) Int. Cl. H03F 3/19

(52) U.S. Cl. CPC H03F 3/19; H03F 2200/294; H03F 2200/451

(57) ABSTRACT

An LNA with inductive source degeneration provided by a degeneration network is presented. The degeneration network includes an inductor in parallel with a stability compensation network for provision of unconditional stability with reduced effect on in-band performance of the LNA. The stability compensation network includes an RLC network comprising a resistor, an inductor and a capacitor in series connection. According to one aspect, a resonant frequency provided by the series-connected inductor and capacitor is selected based on a known frequency of instability. Values of the resistor, inductor and capacitor are iteratively derived based on an optimization routine with criteria that includes a magnitude of the μ-factor. The criteria further include an in-band RF performance of the LNA. According to another aspect, initial values of the inductor and capacitor are selected for an initial value of the resonant frequency to be equal to about 10× the in-band frequency.

### TECHNICAL FIELD

The present application is related to electronic radio frequency (RF) circuits, and more particularly to stability enhancement for low noise amplifiers (LNAs) with inductive source degeneration.

### BACKGROUND

FIG. 1A shows a simplified schematic of a prior art low noise amplifier (LNA, 100A) that may be used, for example, in a receive side of an RF system, such as, for example, an RF frontend (RFFE). In such an RF system, part of, for example, a handheld device, an RF signal received at an antenna may be provided as an input RF signal, RF_{IN}, to the LNA (100A). In turn, the LNA (100A) may amplify the input RF signal, R_{FIN}, to output a corresponding amplified output RF signal, RF_{OUT}. Processing (e.g., amplification) of the input RF signal, RF_{IN}, may be provided through a cascode configuration (M1, M2, a cascode arrangement, a cascode amplifier) comprising an input transistor, M1, that is in series connection with an output cascode transistor, M2. As known to a person skilled in the art, biasing of the cascode configuration (M1, M2) may be provided via (gate) biasing signals (V_{G1}, V_{G2}) provided/coupled (e.g., via one or more of, for example, inductor, resistor, transformer, switch, etc.) to gates of the transistors (M1, M2), in combination with a supply voltage, V_{DD}, that is coupled to a drain of the output cascode transistor, M2, through an inductor, L_{OUT}, and a reference ground, Gnd, that is coupled to a source, Si, of the input transistor, M1, through a degeneration inductor, L_{DEG}. A person skilled in the art would recognize that the input transistor, M1, is configured as a common source transistor, the output cascode transistor, M2, is configured as a common gate transistor, and the LNA configuration (100A) may be referred to as an inductively degenerated common source LNA.

With continued reference to FIG. 1A, an input match circuit to the cascode configuration (M1, M2) may include an inductor, L_{IN}, that couples the input RF signal, RF_{IN}, to a gate of the input transistor, M1. As known to a person skilled in the art, a value (inductance) of the (input match) inductor, L_{IN}, may be selected to reduce, at a desired operating frequency (e.g., a frequency band of operation) of the LNA (100A), loss of the input RF signal, RF_{IN}, when coupled to the input transistor, M1 (e.g., input return loss). Furthermore, a capacitor, C_{IN}, coupled between the inductor, L_{IN}, and the gate of the input transistor, M1, may serve as an AC coupling capacitor.

As it is well known to a person skilled in the art, the degeneration inductor, L_{DEG}, that is coupled to the source, Si, of the input transistor, M1, may be selected to provide an input impedance of the LNA (100A) which in combination with internal parameters (e.g., gate-to-source capacitance) of the input transistor, M1, may present a resonance at the (center) frequency of operation of the LNA (100A). In some cases, multi-gain functionality of the LNA (100A) may be provided by changing (e.g., tuning, switching) inductance provided by the degeneration inductor, L_{DEG}.

Although operation of the LNA (100A) may be in view of one or more specific (narrow-) frequency bands of operation, in some cases out of band behavior of the LNA (100A) may be considered an important design aspect. In other words, design of the LNA (100A) may be in view of a broadband frequency response of the LNA (100A), including, for example, a requirement/desire to prevent/reduce instabilities/oscillations over the broadband frequency range irrespective of various (even unexpected) input and/or output load conditions. Prior art implementations for preventing/reducing instabilities/oscillations may include coupling a stability compensation network comprising a resistor and/or capacitor in parallel with the degeneration inductor, L_{DEG}. The combination of such stability compensation network with the degeneration inductor, L_{DEG}, may be referred to as a degeneration network.

For example, the degeneration network of the prior art LNA (100B) shown in FIG. 1B includes a stability compensation network, N_{cmp1B}, that consists of a resistor, R_{cmp1}, arranged in parallel with the degeneration inductor, L_{DEG}. In such implementation, the resistor, R_{cmp1}, is configured to detune (i.e., lower the Q-factor of) the degeneration inductor, L_{DEG}, based on a ratio of its inductive reactance to its resistance at broadband frequencies. Although inclusion of the stability compensation network, N_{cmp1B}, may allow decrease of instabilities over the broadband frequency range (e.g., in-band frequency and out of band frequency), the detuning of the degeneration inductor, L_{DEG}, including detuning within a frequency band of operation (e.g., in-band) of the LNA (100B), may degrade a noise figure (i.e., signal-to-noise figure) performance of the LNA (100B), and therefore a sensitivity of the LNA (100B). Furthermore, in some cases, low values of the resistor, R_{cmp1}, which may be desirable for reducing in-band and higher frequency instabilities, may short the degeneration inductor, L_{DEG}, thereby potentially causing undesired instabilities at lower frequencies (e.g., lower than in-band frequency). On the other hand, restricting the values of the resistor, R_{cmp1}, to higher values in order to prevent the low frequency instabilities, may negatively affect performance of the stability compensation network, N_{cmp1B}, in reducing of the in-band and higher frequency instabilities. In other words, selection of the value of the resistor, R_{cmp1}, of the stability compensation network, N_{cmp1B}, of FIG. 1B may be based on a tradeoff between effective reduction of (potential) instabilities at low frequencies or instabilities at in-band or higher frequencies.

The degeneration network of the prior art LNA (100C) shown in FIG. 1C includes a stability compensation network, N_{cmp1C}, that consists of a resistor, R_{cmp1}, in series connection with a capacitor, C_{cmp1}, the series-connected resistor R_{cmp1}, and capacitor, C_{cmp1}, arranged in parallel with the degeneration inductor, L_{DEG}. When compared to the prior art LNA (100B) of FIG. 1B, at low frequencies, the series-connected capacitor, C_{cmp1}, of the stability compensation network, N_{cmp1C}, exhibits a high impedance which prevents the shorting of the degeneration inductor, L_{DEG}, thereby preventing the (low frequency) instabilities of the LNA (100B). On the other hand, at higher frequencies, the series-connected capacitor, C_{cmp1}, of the stability compensation network, N_{cmp1C}, exhibits a low impedance (e.g., short), thereby providing a behavior similar to the behavior of the degeneration network of the LNA (100B) that is based on a single resistor in parallel with the degeneration inductor, L_{DEG}, including, for example, the detuning of the degeneration inductor, L_{DEG}.

Differently from the stability compensation network, N_{cmp1B}, of the LNA (100B), the stability compensation network, N_{cmp1C}, of the LNA (100C) may target instability above certain frequency. At (target) frequencies that are within five times (5X) the frequency band of operation of the LNA (100C), the series-connected capacitor, C_{cmp1}, of the stability compensation network, N_{cmp1C}, may require a larger capacitance in order to reduce the instabilities. However, such larger capacitance may negatively affect in-band performance of the LNA (100C). In other words, selection of the value of the capacitor, C_{cmp1}, of the stability compensation network, N_{cmp1C}, of FIG. 1C may be based on a tradeoff between effective reduction of instabilities at frequencies close to (e.g., within 5×) the in-band frequency or an in-band performance of the LNA (100C).

Teachings according to the present disclosure describe a degeneration network that includes a stability compensation network including series-connected resistor, capacitor and inductor that target specific instability frequencies of an LNA while overcoming the above-described shortcomings of the prior art.

### SUMMARY

According to a first aspect of the present disclosure, a low noise amplifier (LNA) is presented, comprising: an input transistor; and a degeneration network having a first terminal connected to a source of the input transistor and a second terminal connected to a reference ground, the degeneration network comprising: a degeneration inductor connected between the first terminal and the second terminal; and a stability compensation network connected between the first terminal and the second terminal, the stability compensation network comprising a resistor, an inductor, and a capacitor in series connection.

According to a second aspect of the present disclosure, a method for providing unconditional stability to an inductively degenerated common source low noise amplifier (LNA) is presented, the method comprising: determining a frequency of instability of the LNA; and coupling a stability compensation network to the source of an input transistor of the LNA, wherein the stability compensation network comprises a resistor, an inductor, and a capacitor in series connection, and respective values of the inductor and capacitor are configured to provide a resonant frequency of the series-connected inductor and capacitor that is based on the frequency of instability of the LNA.

Further aspects of the disclosure are provided in the description, drawings and claims of the present application.

### BRIEF DESCRIPTION OF THE DRAWINGS

The accompanying drawings, which are incorporated into and constitute a part of this specification, illustrate one or more embodiments of the present disclosure and, together with the description of example embodiments, serve to explain the principles and implementations of the disclosure.

FIG. 1A shows a simplified schematic of a prior art low noise amplifier (LNA) with inductive source degeneration provided by an inductor.

FIG. 1B shows a simplified schematic of a prior art low noise amplifier (LNA) with inductive source degeneration provided by a degeneration network that includes a resistor in parallel with a degeneration inductor.

FIG. 1C shows a simplified schematic of a prior art low noise amplifier (LNA) with inductive source degeneration provided by a degeneration network that includes a series connection of a resistor and a capacitor in parallel with a degeneration inductor.

FIG. 2A shows a simplified schematic of a low noise amplifier (LNA) with inductive source degeneration provided by a degeneration network according to an embodiment of the present disclosure.

FIG. 2B shows various exemplary implementations of degeneration networks according to the present disclosure.

FIG. 3 shows a diagram representative of a stability criteria based on scattering parameters of a two-port network/circuit.

FIG. 4 shows graphs representative of stability performance provided by the degeneration network according to the present disclosure.

FIG. 5 shows various process steps of a method according to the present disclosure.

Like reference numbers and designations in the various drawings indicate like elements.

### DETAILED DESCRIPTION

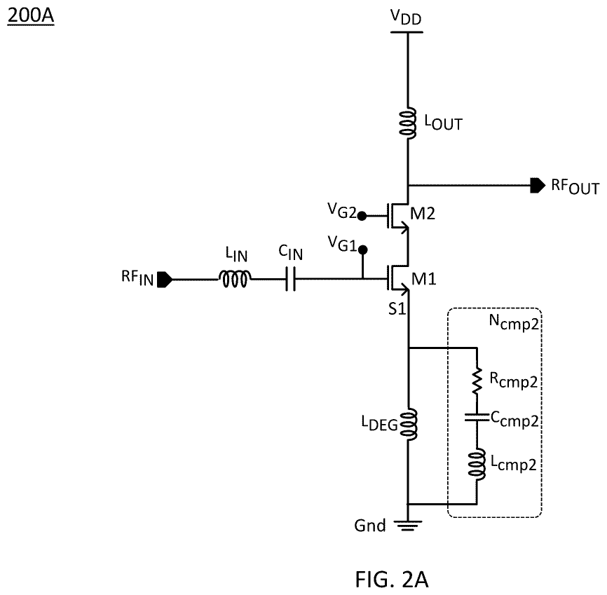

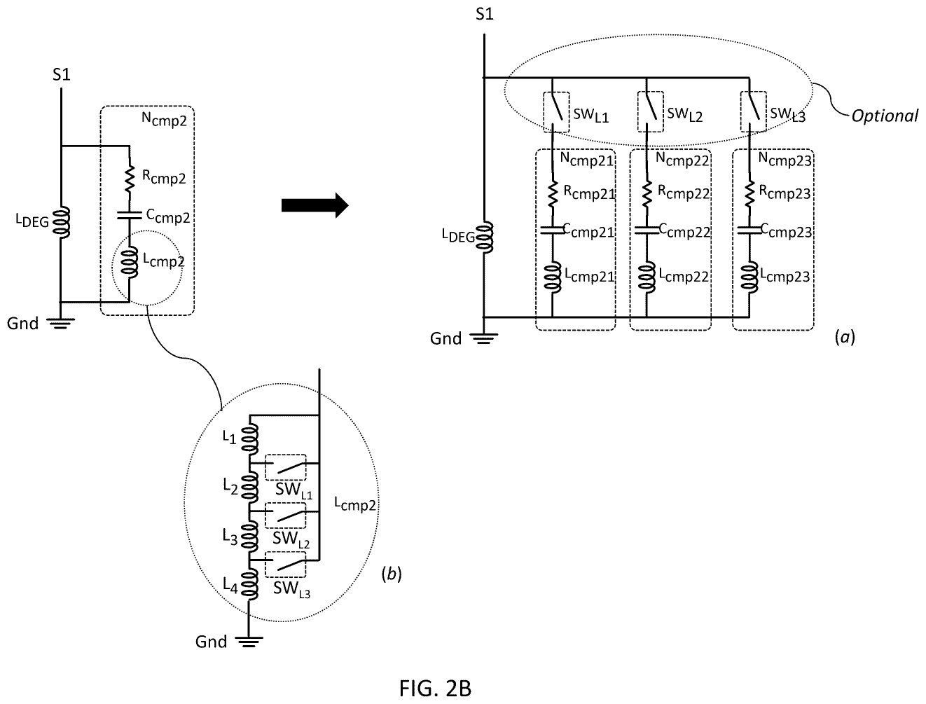

Teachings according to the present disclosure overcome the above-described shortcoming by providing, as shown in the LNA (200A) of FIG. 2A, a degeneration network that includes a series connection of a resistor, R_{cmp2}, an inductor, L_{cmp2}, and a capacitor, C_{cmp2}, in parallel with the degeneration inductor, L_{DEG}. In other words, stability compensation for the degeneration network according to the present disclosure may be provided by a RLC network, N_{cpm2}, that is connected in parallel with the degeneration inductor, L_{DEG}, wherein the RLC network, N_{cpm2}, provided by the series-connected (R_{cmp2}, L_{cmp2}, C_{cmp2}) may be considered as a stability compensation network (of the degeneration network).

The stability compensation network, N_{cpm2}, according to the present disclosure may be designed to target specific frequencies of instabilities of the LNA (200A), whether such frequencies may be lower or higher than the frequencies of operation (e.g., in-band frequency of operation, center frequency of operation) of the LNA (200A). Furthermore, added flexibility provided by the stability compensation network, N_{cpm2}, may allow to target, and therefore eliminate, the instabilities, irrespective of their proximity to (e.g., distance from) the frequencies of operation of the LNA (200A) with minimal or reduced effect in the in-band (RF) performance of the LNA. It should be noted that teachings according to the present disclosure may equally apply to LNA cascode configurations that include more than one cascode transistor, including two, three, four or more cascode transistors that are in series connection with one another. Furthermore, teachings according to the present disclosure may not be limited to LNA's based on cascode configurations, rather, the present teachings may equally apply to an LNA configuration comprising a single (input/output) transistor, and therefore devoid of a cascode transistor.

Such added flexibility may be provided by a resonant frequency of the series-connected inductor, L_{cmp2}, with the capacitor, C_{cmp2}, of the stability compensation network, N_{cpm2}, which may allow to target any frequency of instability (e.g., instability frequency) effectively and robustly outside the in-band frequency, and therefore, provide a much-desired unconditional stability of the LNA (200A). As used herein, unconditional stability of an LNA (e.g., 200A) may be referred to lack of any frequency of instability of the LNA over the broadband frequency range (e.g., entire frequency spectrum) irrespective of input and/or output load conditions. Such unconditional stability may therefore allow a chip manufacturer to, for example, ship/sell its product (e.g., LNA chip/module) to a system integrator for integration within a device while guaranteeing its stability irrespective of input/output loads provided by the integration.

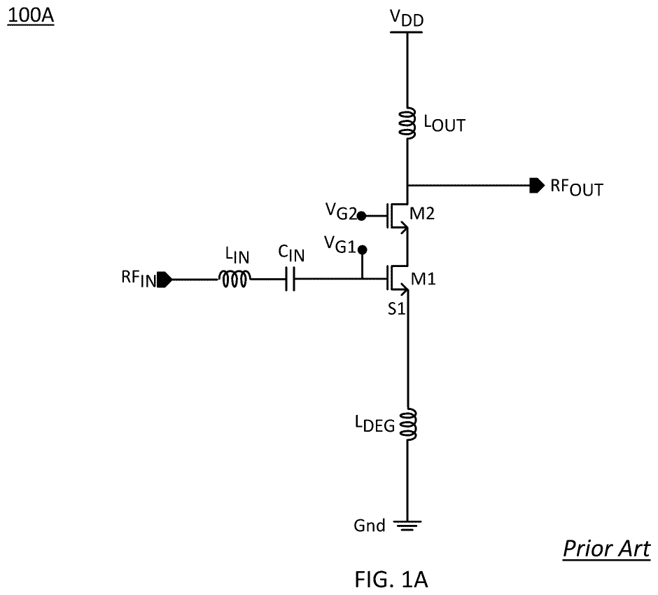

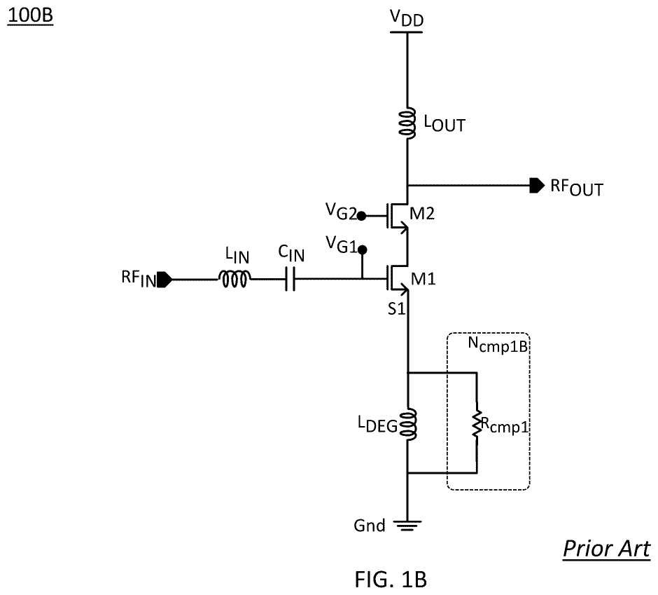

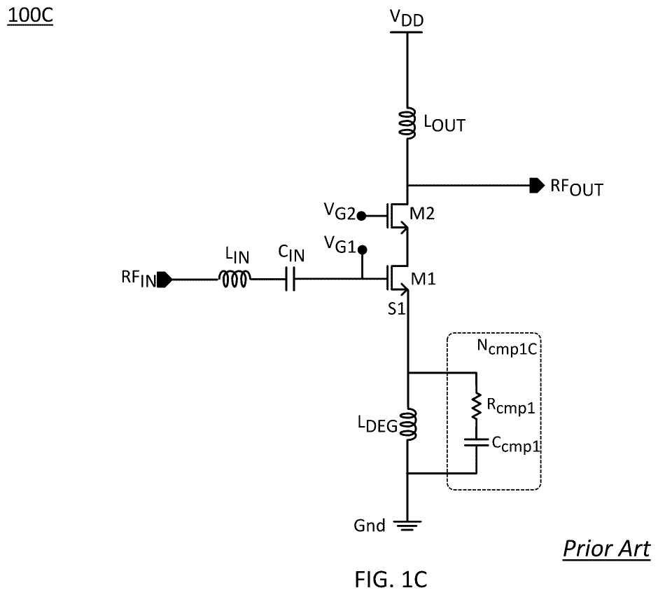

According to an embodiment of the present disclosure, a frequency of instability targeted by the stability compensation network, N_{cpm2}, of the LNA (200A) may be (first) determined via simulation programs that consider a circuital layout and component values of the LNA (200A) without considering presence of the stability compensation network (e.g., N_{cpm2}). In other words, a frequency of instability may be first determined based on the basic inductively degenerated LNA (100A) of FIG. 1A, following which component values of the stability compensation network (e.g., N_{cpm2}) that target the frequency of instability may be determined. Subsequently, same simulation programs may be used to verify lack of any frequency of instability (e.g., unconditional stability) for the combined circuital layout, i.e., the LNA (200A). Furthermore, based on the verification, and if any frequency of instability remains (i.e., for the combined circuital layout, LNA 200A), more/successive iterations of the determining of the component values (e.g., converging) followed by the verification may be performed till the component values convergence to provide unconditional stability of the LNA (200A).

According to an embodiment of the present disclosure, determination of the frequencies of instability of a two-port network/circuit, such as the inductively degenerated LNA (100A/200A) of FIGS. 1A/2A, may include assessing (a magnitude of) the μ-factor (i.e., Mu-factor) of the two-port network/circuit. As known to a person skilled in the art, the μ-factor of the two-port network/circuit, such as the LNA (100A/200A), may be used to determine stability criteria of the two-port network/circuit based on corresponding (well known in the art) scattering parameters (i.e., S₁₁, S₁₂, S₂₁, S₂₂). Not only the μ-factor can be used as a test for unconditional stability (i.e., magnitude strictly greater than 1, i.e., |μ-factor|>1), but also a magnitude of the μ-factor can be used to determine an available margin of the unconditional stability. In other words, the greater the distance of the magnitude of the μ-factor from 1, the stronger/more robust the unconditional stability.

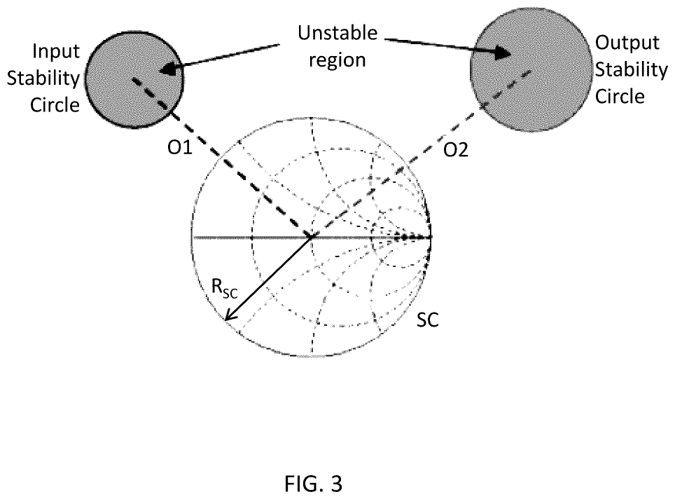

A representative diagram of the μ-factor for a two-port network/circuit is shown in FIG. 3. In particular, FIG. 3 represents distances O1 and O2 from the center of the Smith chart, SC, to respective centers of input stabilities (e.g., input stability circle) and output stabilities (e.g., output stability circle). A stability circle, such as the input or output stability circle shown in FIG. 3, may be considered as a circle on the Smith chart, SC, that represents the boundary between those values of source (e.g., input) or load (e.g., output) impedance that cause instability and those that do not. The μ-factor can be considered as the distance from the center of the Smith chart, SC, to the nearest point of instability provided by the (combination of the) two circles shown in FIG. 3. Because the radius of the Smith chart, SC, is equal to one (i.e., 1), then a magnitude of the μ-factor strictly greater than one (i.e., |μ-factor|>1) may be considered as a sufficient condition for unconditional instability.

It should be noted that teachings according to the present disclosure may not be limited to use of the μ-factor for determining stability of an inductively degenerated LNA (e.g., LNA 100A/200A). Other methods for determination (and verification) of a frequency of instability may include, for example, use of the known in the art K-factor from which the μ-factor is derived, or even testing of a broadband frequency response of an actual circuital implementation of the LNA and identifying frequencies of instability via presence of corresponding oscillations. A person skilled in the art may know of other methods for determination (and verification) of the frequencies of instability of an inductively degenerated LNA, all of which may be considered compatible with the stability compensation network (e.g., N_{cpm2}) according to the present teachings. Once a frequency of instability is determined, then values of the components (R_{cmp2}, L_{cmp2}, C_{cmp2}) of the stability compensation network, N_{cpm2}, may be derived (and iteratively optimized) in view of such frequency of instability and in further view of a frequency range of operation of the LNA. It should be noted that although a sequence in the series connection of the components (R_{cmp2}, L_{cmp2}, C_{cmp2}) may slightly affect the coupling effect of the stability compensation network, N_{cpm2}, over the LNA (e.g., source of transistor M1), teachings according to the present disclosure may equally apply to any sequence in the series connection.

With reference back to FIG. 2A, according to an embodiment of the present disclosure, values (e.g., L and C) of the components (L_{cmp2}, C_{cmp2}) of the compensation network, N_{cpm2}, may be selected so that a resonant frequency (e.g., proportional to LC^{-1/2}) of the series-connected inductor, L_{cmp2}, with the capacitor, C_{cmp2}, may be at, or close to, a (known) frequency of instability of the LNA (200A). According to an embodiment of the present disclosure, values of such components may be further selected in view of a proximity of the frequency of instability to a frequency of operation of the LNA (200A). According to an embodiment of the present disclosure, such component values may be selected so that the resonant frequency of the series-connected inductor, L_{cmp2}, with the capacitor, C_{cmp2}, may be at a frequency that is equal to, or greater than, ten times (e.g., 10×) the center frequency of operation of the LNA (200A) while remaining close to, or equal to, the frequency of instability. Accordingly, if the frequency of instability is greater than 10× the (center) frequency of operation, the resonance frequency provided by the series-connected inductor, L_{cmp2}, with the capacitor, C_{cmp2}, may be equal to, or close to (e.g., +/−20%), the frequency of instability.

With continued reference to FIG. 2A, for a case of a frequency of instability that is smaller than 10× the (center) frequency of operation of the LNA (200A), the values of the components (L_{cmp2}, C_{cmp2}) of the compensation network, N_{cpm2}, may be initially selected so that a resonant frequency of the series-connected inductor, L_{cmp2}, with the capacitor, C_{cmp2}, may be equal to about 10× the (center) frequency of operation of the LNA (200A). Subsequent iterations provided, for example, by sweeping values of the components (R_{cmp2}, L_{cmp2}, C_{cmp2}) to optimize the magnitude of the of the μ-factor for provision of unconditional stability (i.e., |μ-factor|>1), may gradually shift the resonant frequency of the series-connected inductor, L_{cmp2}, with the capacitor, C_{cmp2}, closer to the frequency of instability while minimizing in-band performance degradation. In other words, as a consequence of such initial selection of the resonant frequency, the optimized value of the μ-factor (i.e., for unconditional stability) may be obtained for a combination of values of the (R_{cmp2}, L_{cmp2}, C_{cmp2}) that provide a resonant frequency that may be greater than the frequency of instability while being sufficiently far from the (center) frequency of operation of the LNA (200A) as to not degrade in-band performance. For example, for a frequency of instability that is about 5× the (center) frequency of operation, the optimized value of the μ-factor may be obtained for values of the (L_{cmp2}, C_{cmp2}) that provide a resonant frequency that is about 7× the (center) frequency of operation. In other words, iterations according to the present disclosure may result in the farthest resonant frequency from the (center) frequency of operation while being sufficiently close to the (targeted) frequency of instability for provision of unconditional stability. It should be noted that in a majority of cases studied by the present inventors, frequencies of instability of an inductively degenerated LNA (e.g., operating in the GHz frequency range and fabricated in CMOS technology) are observed in a range from about 5× to 10× the frequency of operation.

With further reference to FIG. 2A, according to an embodiment of the present disclosure, a value of the inductor, L_{cmp2}, of the compensation network, N_{cpm2}, may be initially selected to be in a range from one tenth (i.e., 1/10) to one twentieth (i.e., 1/20) of a value of the degeneration inductor, L_{DEG}. Based on such initially selected value of the inductor, L_{cmp2}, a value of the capacitor, C_{cmp2}, of the compensation network, N_{cpm2}, may be selected so that the resonant frequency of the series-connected inductor, L_{cmp2}, with the capacitor, C_{cmp2}, may be at a frequency that is equal to (about) ten times (e.g., 10×) the center frequency of operation of the LNA (200A).

According to an embodiment of the present disclosure, a value of the resistor, R_{cmp2}, of the compensation network, N_{cpm2}, may be sufficiently small as to not dominate impedance of the compensation network, N_{cpm2}, making the compensation network high impedance at instability frequency, but sufficiently large as to introduce some (resistive) loss in the compensation network, N_{cpm2}, so to control/tweak effectiveness of said network in targeting of the frequency of instability (while not degrading in-band performance). Accordingly, in the first order, the resistor, R_{cmp2}, may not affect the resonant frequency provided by (L_{cmp2}, C_{cmp2}).

According to an exemplary embodiment of the present disclosure, a value of the resistor, R_{cmp2}, may be in a range from few Ohms to several tens of Ohms. According to an embodiment of the present disclosure, the resistor, R_{cmp2}, may be encompassed within the inductor, L_{cmp2}. In other words, the inductor, L_{cmp2}, may be realized such to include a self-inductance providing the inductance of the inductor, and an equivalent series resistance providing the resistance of the resistor, R_{cmp2}. According to an exemplary embodiment of the present disclosure, the equivalent series resistance of the inductor, L_{cmp2}, may provide a portion, or entirety, of the resistance of the resistor, R_{cmp2}. Such realization of the in inductor, L_{cmp2}, to provide the resistance of the resistor, R_{cmp2}, may advantageously reduce a size of a physical layout of the LNA (200A).

With further reference to FIG. 2A, once initial values of the components (R_{cmp2}, L_{cmp2}, C_{cmp2}) of the stability compensation network, N_{cpm2}, are selected, successive iterations for optimization of the μ-factor according to the above description may be performed. It should be noted that criteria for optimization may include not only arriving at a μ-factor representing unconditional stability, but also a reduced/minimal degradation for in-band (RF) performance of the LNA (200A). According to an embodiment of the present disclosure, a criteria for optimization may include obtaining an impedance value of the series-connected inductor, L_{cmp2}, with the capacitor, C_{cmp2}, that is equal to, or greater than, ten times (i.e., 10×) the impedance of the degeneration inductor, L_{DEG}, at the frequency of operation of the LNA (200A). Such impedance value of the series-connected components (L_{cmp2}, C_{cmp2}) may be sufficiently small not to degrade in-band performance of the LNA (200A).

FIG. 2B shows various exemplary implementations of degeneration networks according to the present disclosure. In particular, shown in FIG. 2B are various switchable configurations that may be used in lieu of, in addition to, or as part of, the (stability) compensation network, N_{cmp2}, described above with reference to FIG. 2A (and shown in the top left of FIG. 2B). In particular, shown in the top right of FIG. 2B, is a switchable configuration (a) that includes a plurality of compensation networks (e.g., N_{cmp21}, N_{cmp22}, N_{cmp23}), each similar to the compensation network, N_{cmp2}, arranged in parallel with the degeneration inductor, L_{DEG}. According to an embodiment of the present disclosure, each of the compensation networks (e.g., N_{cmp21}, N_{cmp22}, N_{cmp23}) may be configured to target a different frequency of instability according to the above description. In other words, values of the respective components (R_{cmp21}, L_{cmp21}, C_{cmp21}), (R_{cmp22}, L_{cmp22}, C_{cmp22}), (R_{cmp23}, L_{cmp23}, C_{cmp23}), of the compensation networks (N_{cmp21}, N_{cmp22}, N_{cmp23}) may be derived according to the above description of the components (R_{cmp2}, L_{cmp2}, C_{cmp2}) of the compensation network, N_{cmp2}, described above with reference to FIG. 2A for targeting a different frequency of instability.

It should be noted that the different frequencies of instability may be based on a fixed/same configuration (e.g., mode of operation) of the LNA (e.g., 200A of FIG. 2A) or on different configuration (e.g., different modes of operation) of the LNA. Accordingly, the plurality of compensation networks (e.g., N_{cmp21}, N_{cmp22}, N_{cmp23}) of the switchable configuration (a) shown in FIG. 2B may be either used concurrently or separately in view of different modes of operation of the LNA, and as dictated by presence of one or more instabilities. It follows that, as shown in the switchable configuration (a) of FIG. 2B, according to an embodiment of the present disclosure each of the plurality of compensation networks (e.g., N_{cmp21}, N_{cmp22}, N_{cmp23}) may be selectively activated or deactivated (e.g., inserted or removed from the degeneration network) via a respective series-connected switch (e.g., SW_{L1}, SW_{L2}, SW_{L3}). It should be noted that operation of the LNA according to different modes of operations may include modes related to different frequency bands, gains, loads, etc.

Shown in the bottom left of FIG. 2B, is a switchable configuration (b) that includes a switchable (e.g., tunable, variable, selectable) inductor, that may be used as the inductor, L_{cmp2}, of the compensation network (e.g., N_{cmp2}) according to the present teachings (and/or as the degeneration inductor, L_{DEG}). As shown in the switchable configuration (b), the switchable inductor may include a plurality of series-connected inductors (e.g., L₁, L₂, L₃, L₄) and a plurality of switches (e.g., SW_{L1}, SW_{L2}, SW_{L3}) configured to short one or more of the inductors, thereby effectively removing the one or more inductors from affecting a combined inductance of the (switchable) inductor, L_{cmp2}. For example, the combined inductance may be respectively provided by the inductance(s) of: (L₁, L₂, L₃, L₄) when all switches are open; (L₂, L₃, L₄) when switch SW_{L1} is closed and all other open; (L₃, L₄) when switch SW_{L2} is closed and switch SW_{L3} is open (and irrespective of a state of the switch SW_{L1}); and L₄ when switch SW_{L3} is closed (and irrespective of states of the switches SW_{L1} and SW_{L2}).

According to an embodiment of the present disclosure, the switchable configuration (b) of FIG. 2B may be used to, for example, in the compensation network (e.g., N_{cmp2}) according to the present teachings to tune the resonant frequency of the series-connected components (L_{cmp2}, C_{cmp2}) of the compensation network, N_{cpm2}. Such tuning may be based, for example, on the operation of the LNA according to different modes of operations. It should be noted that in addition to, or in combination with, a switchable inductor according to the switchable configuration (b), a switchable (e.g., tunable, variable, selectable) capacitor may be used as the capacitor, C_{cmp2}, of the compensation network, N_{cpm2}, for added flexibility in tuning of the resonant frequency.

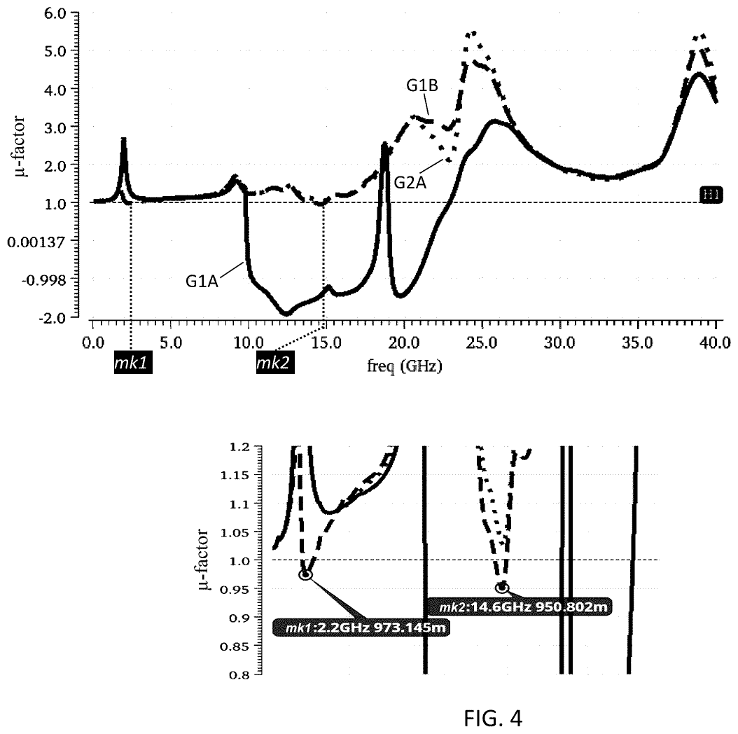

FIG. 4 (top of the figure) shows graphs representative of stability performance provided by the degeneration network according to the present disclosure, including the compensation network according to the present disclosure (e.g., Ncmp2 of FIG. 2A) in parallel with a degeneration inductor (e.g., L_{DEG} of FIG. 2A), when used in an inductively degenerated LNA (e.g., 200 of FIG. 2A). In particular, the graph labeled as G1A represents the magnitude of the μ-factor for the prior art LNA (100A) described above with reference to FIG. 1A, the graph labeled as G1B represents the magnitude of the μ-factor for the prior art LNA (100B) described above with reference to FIG. 1B, and the graph labeled as G2A represents the magnitude of the pa-factor for the LNA (200A) according to the present disclosure described above with reference to FIG. 2A.

With continued reference to FIG. 4, graph G1A shows clear frequencies/ranges of instability (e.g., 10-18 GHz and 19-23 GHz) which may be substantially reduced, but not eliminated for provision of unconditional stability. Accordingly, as shown in the graph G1B, two frequencies of instability (e.g., mk1 and mk2) may still exist in the prior art LNA (100B of FIG. 1B). As shown in the zoomed/expanded graphs in the bottom of FIG. 4, such frequencies of instability, corresponding to respective values of the magnitude of the μ-factor being ≤1, may be at about 2.2 GHz and 14.6 GHz. By coupling the (stability) compensation network according to the present disclosure (e.g., N_{cpm2}) in parallel with the degeneration inductor (e.g., L_{DEG}), as shown in the graph G2A of FIG. 4, including in the zoomed/expanded graph, the instability frequencies of the configuration according to the graph G1B are removed, thereby obtaining unconditional stability.

It should be noted that the graphs represented in FIG. 4 correspond to respective LNA operation according to a center frequency equal to about 1.9 GHz. Furthermore, unconditional stability according to the graph G2A is provided via optimized values of the components (R_{cmp2}, L_{cmp2}, C_{cmp2}) of the stability compensation network, N_{cpm2}, equal to (10 Ohms, 0.25 nH, 0.72 pF). Furthermore, increased in-band performance of the configuration (e.g., 200A) represented by the graph G2A is obtained compared to an in-band performance provided by the configuration (e.g., 100B) represented by the graphs G1B. These include, for example, a (minimum) noise figure (NFmin) performance slightly degraded (e.g., about 40 mdB) from the nominal NFmin of the configuration represented by the graph G1A (e.g., LNA 100A) as compared to a substantial degradation of the NFmin (e.g., about 120 mdB) of the configuration represented by the graph G1B. Same comparative in-band performances can be observed with respect to the input reflection coefficient (e.g., S11, input matching) that is about 2 dB degraded in the configuration represented by the graph G2A compared to over 10 dB degradation in the configuration represented by the graph G1B. In other words, in contrast to the prior art stability compensation networks (e.g., per FIGS. 1B/1C), the stability compensation network according to the present teachings advantageously provide unconditional stability without (substantially) scarifying in-band performance.

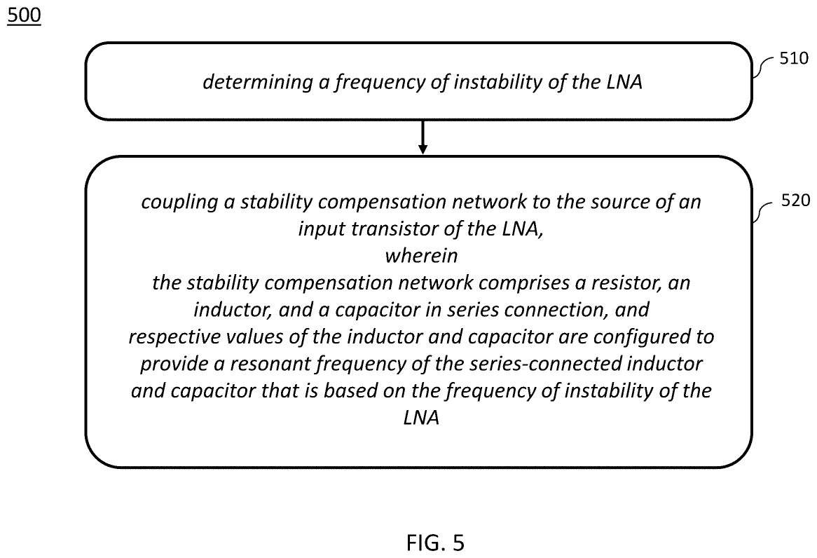

FIG. 5 is a process chart (500) showing various steps of a method according to the present disclosure for providing unconditional stability to an inductively degenerated common source low noise amplifier (LNA). As shown in FIG. 5, such steps include: determining a frequency of instability of the LNA, according to step (510); and coupling a stability compensation network to the source of an input transistor of the LNA, according to step (520). According to some aspects of the present disclosure, the stability compensation network comprises a resistor, an inductor, and a capacitor in series connection, and respective values of the inductor and capacitor are configured to provide a resonant frequency of the series-connected inductor and capacitor that is based on the frequency of instability of the LNA.

Applications that may include the novel apparatus and systems of various embodiments include electronic circuitry used in high-speed computers, communication and signal processing circuitry, modems, single or multi-processor modules, single or multiple embedded processors, data switches, and application-specific modules, including multilayer, multi-chip modules. Such apparatus and systems may further be included as sub-components within a variety of electronic systems, such as televisions, cellular telephones, personal computers (e.g., laptop computers, desktop computers, handheld computers, tablet computers, etc.), workstations, radios, video players, audio players (e.g., mp3 players), vehicles, medical devices (e.g., heart monitor, blood pressure monitor, etc.) and others. Some embodiments may include a number of methods.

The term “MOSFET” technically refers to metal-oxide-semiconductor-field-effect-transistors; another synonym for MOSFET is “MISFET”, for metal-insulator-semiconductor FET. However, “MOSFET” has become a common label for most types of insulated-gate FETs (“IGFETs”). Despite that, it is well known that the term “metal” in the names MOSFET and MISFET is now often a misnomer because the previously metal gate material is now often a layer of polysilicon (polycrystalline silicon). Similarly, the “oxide” in the name MOSFET can be a misnomer, as different dielectric materials are used with the aim of obtaining strong channels with smaller applied voltages. Accordingly, the term “MOSFET” as used herein is not to be read as literally limited to metal-oxide-semiconductor FETs, but instead includes IGFETs in general.

As should be readily apparent to one of ordinary skill in the art, various embodiments of the invention can be implemented to meet a wide variety of specifications. Unless otherwise noted above, selection of suitable component values is a matter of design choice and various embodiments of the invention may be implemented in any suitable IC technology (including but not limited to MOSFET and IGFET structures), or in hybrid or discrete circuit forms. Integrated circuit embodiments may be fabricated using any suitable substrates and processes, including but not limited to standard bulk silicon, silicon-on-insulator (SOI), silicon-on-sapphire (SOS), GaN HEMT, GaAs pHEMT, and MESFET technologies. However, the inventive concepts described above are particularly useful with an SOI-based fabrication process (including SOS), and with fabrication processes having similar characteristics. Fabrication in CMOS on SOI or SOS enables low power consumption, the ability to withstand high power signals during operation due to FET stacking, good linearity, and high frequency operation (in excess of about 10 GHz, and particularly above about 20 GHz). Monolithic IC implementation is particularly useful since parasitic capacitances generally can be kept low (or at a minimum, kept uniform across all units, permitting them to be compensated) by careful design.

Voltage levels may be adjusted or voltage and/or logic signal polarities reversed depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functions without significantly altering the functionality of the disclosed circuits.

The examples set forth above are provided to give those of ordinary skill in the art a complete disclosure and description of how to make and use the embodiments of the gate drivers for stacked transistor amplifiers of the disclosure and are not intended to limit the scope of what the applicant considers to be the invention. Such embodiments may be, for example, used within mobile handsets for current communication systems (e.g., WCDMA, LTE, WiFi, etc.) wherein amplification of signals with frequency content of above 100 MHz and at power levels of above 50 mW may be required. The skilled person may find other suitable implementations of the presented embodiments.

Modifications of the above-described modes for carrying out the methods and systems herein disclosed that are obvious to persons of skill in the art are intended to be within the scope of the following claims. All patents and publications mentioned in the specification are indicative of the levels of skill of those skilled in the art to which the disclosure pertains. All references cited in this disclosure are incorporated by reference to the same extent as if each reference had been incorporated by reference in its entirety individually.

It is to be understood that the disclosure is not limited to particular methods or systems, which can, of course, vary. It is also to be understood that the terminology used herein is for the purpose of describing particular embodiments only and is not intended to be limiting. As used in this specification and the appended claims, the singular forms “a”, “an”, and “the” include plural referents unless the content clearly dictates otherwise. The term “plurality” includes two or more referents unless the content clearly dictates otherwise. Unless defined otherwise, all technical and scientific terms used herein have the same meaning as commonly understood by one of ordinary skill in the art to which the disclosure pertains.

A number of embodiments of the disclosure have been described. Nevertheless, it will be understood that various modifications can be made without departing from the spirit and scope of the present disclosure. Accordingly, other embodiments are within the scope of the following claims.

1. A low noise amplifier (LNA), comprising:
an input transistor; and
a degeneration network having a first terminal connected to a source of the input transistor and a second terminal connected to a reference ground, the degeneration network comprising:
a degeneration inductor connected between the first terminal and the second terminal; and
a stability compensation network connected between the first terminal and the second terminal, the stability compensation network comprising a resistor, an inductor, and a capacitor in series connection.

2. The low noise amplifier (LNA) of claim 1, wherein:
the stability compensation network is configured to provide unconditional stability of the LNA.

3. The low noise amplifier (LNA) of claim 1, wherein:
respective values of the inductor and capacitor are configured to provide a resonant frequency of the series-connected inductor and capacitor that is based on a frequency of instability provided by the LNA in the absence of the stability compensation network.

4. The low noise amplifier (LNA) of claim 3, wherein:
the resonant frequency is equal to, or greater, than the frequency of instability.

5. The low noise amplifier (LNA) of claim 3, wherein:
the frequency of instability is greater than ten times an in-band frequency of operation of the LNA, and
the resonant frequency is substantially equal to the frequency of instability.

6. The low noise amplifier (LNA) of claim 3, wherein:
the frequency of instability is smaller than ten times an in-band frequency of operation of the LNA, and
the resonant frequency is greater than the frequency of instability.

7. The low noise amplifier (LNA) of claim 6, wherein:
the resonant frequency is about twenty percent greater than the frequency of instability.

8. The low noise amplifier (LNA) of claim 3, wherein:
the resonant frequency is in range from minus twenty percent to plus twenty percent the frequency of instability.

9. The low noise amplifier (LNA) of claim 3, wherein:
the respective values of the inductor and capacitor are further configured to provide an impedance of the series-connected inductor and capacitor that is equal to, or greater than, ten times an impedance of the degeneration inductor, L_{DEG}, at the in-band frequency of operation of the LNA.

10. The low noise amplifier (LNA) of claim 3, wherein:
the respective value of the inductor is in a range from one tenth to one twentieth of a value of the degeneration inductor.

11. The low noise amplifier (LNA) of claim 3, wherein:
the respective values of the inductor and capacitor, in combination with a respective value of the resistor, are configured to provide a magnitude of a μ-factor calculated from an equivalent two-port scattering parameters of the LNA to be strictly greater than one for the provision of unconditional stability of the LNA.

12. The low noise amplifier (LNA) of claim 11, wherein:
the respective values of the inductor, capacitor, and resistor, are derived from an iterative process that optimizes:
the magnitude of the μ-factor for provision of the unconditional stability, and
an in-band RF performance of the LNA, including a noise figure and an input reflection factor.

13. The low noise amplifier (LNA) of claim 12, wherein:
the iterative process includes an initial set of the respective values that include:
an initial value of the inductor that is in a range from one tenth to one twentieth of a value of the degeneration inductor, and
an initial value of the capacitor that in combination with initial value of the inductor provides a resonant frequency of the series-connected inductor and capacitor that is equal to ten times an in-band frequency of operation of the LNA.

14. The low noise amplifier (LNA) of claim 1, further comprising:
one or more additional stability compensation networks respectively connected between the first terminal and the second terminal, each of the one or more stability compensation networks comprising a respective additional resistor, inductor, and capacitor in series connection.

15. The low noise amplifier (LNA) of claim 14, further comprising at least one switch in series connection between:
the first terminal, and
the stability compensation network or one of the one or more additional stability compensation networks.

16. The low noise amplifier (LNA) of claim 1, further comprising:
an output cascode transistor in series connection with the input transistor.

17. The low noise amplifier (LNA) of claim 16, wherein:
the output cascode transistor is coupled to a supply voltage through a load inductor.

18. A method for providing unconditional stability to an inductively degenerated common source low noise amplifier (LNA), the method comprising:
determining a frequency of instability of the LNA; and
coupling a stability compensation network to the source of an input transistor of the LNA, wherein
the stability compensation network comprises a resistor, an inductor, and a capacitor in series connection, and
respective values of the inductor and capacitor are configured to provide a resonant frequency of the series-connected inductor and capacitor that is based on the frequency of instability of the LNA.

19. The method according to claim 18, wherein:
the resonant frequency is in range from minus twenty percent to plus twenty percent the frequency of instability.

20. The method according to claim 18, wherein:
the respective values of the inductor and capacitor, in combination with a respective value of the resistor, are configured to provide a magnitude of a μ-factor calculated from an equivalent two-port scattering parameters of the LNA to be strictly greater than one for the provision of the unconditional stability.

21. The method according to claim 20, further comprising:
determining the respective values of the inductor, capacitor, and resistor, from an iterative process that optimizes:
the magnitude of the μ-factor for provision of the unconditional stability, and
an in-band RF performance of the LNA, including a noise figure and an input reflection factor,
wherein iterative process includes an initial set of the respective values that include:
an initial value of the inductor that is in a range from one tenth to one twentieth of a value of a degeneration inductor connected to the source of the input transistor, and
an initial value of the capacitor that in combination with initial value of the inductor provides a resonant frequency of the series-connected inductor and capacitor that is equal to ten times an in-band frequency of operation of the LNA.
